(19) United States
(12) Patent Application Publication
(10) Pub. No.: US 2025/0174462 A1
(43) Pub. Date: May 29, 2025

(54) SUBSTRATE PROCESSING METHOD AND SUBSTRATE PROCESSING SYSTEM

(71) Applicant: Tokyo Electron Limited, Tokyo (JP)

(72) Inventors: Takuya SEINO, Gyeonggi-do (KR); Yasuhiro HAMADA, Yamanashi (JP); Tadashi MITSUNARI, Yamanashi (JP); Miyako KANEKO, Yamanashi (JP)

(21) Appl. No.: 18/954,360

(22) Filed: Nov. 20, 2024

(30) Foreign Application Priority Data
Nov. 28, 2023 (JP) 2023-200352

(51) Int. Cl. H01L 21/3065; H01J 37/32; H01L 21/02; H01L 21/311

(52) U.S. Cl. CPC H01L 21/3065; H01J 37/32449; H01L 21/02164; H01L 21/0217; H01L 21/31116; H01L 21/31144; H01J 2237/334

(57) ABSTRACT

A substrate processing method include (a) providing a substrate including an etching target film and a mask on the etching target film, the mask including sidewalls defining at least one opening, (b) selectively forming an additional mask containing carbon on the mask by using plasma generated from a processing gas containing carbon and hydrogen, and (c) etching the etching target film by using plasma generated from an etching gas.

### CROSS-REFERENCE TO RELATED APPLICATIONS

The present application claims priority under 35 U.S.C. § 119 to Japanese Patent Application No. 2023-200352 filed on Nov. 28, 2023, the entire contents of which are incorporated herein by reference.

### TECHNICAL FILD

An exemplary embodiment of the present disclosure relates to a substrate processing method and a substrate processing system.

### BACKGROUND

JP2021-118304A discloses a technology of etching a film stack of a silicon-containing film.

### SUMMARY

A substrate processing method in one exemplary embodiment of the present disclosure include:
(a) providing a substrate including an etching target film and a mask on the etching target film, the mask including sidewalls defining at least one opening,
(b) selectively forming an additional mask containing carbon on the mask by using plasma generated from a processing gas containing carbon and hydrogen, and
(c) etching the etching target film by using plasma generated from an etching gas.

### BRIEF DESCRIPTION OF DRAWINGS

FIG. 1 is a diagram illustrating a configuration example of a plasma processing system.

FIG. 2 is a diagram illustrating a configuration example of a capacitively coupled plasma processing apparatus.

FIG. 3 is a diagram illustrating a configuration example of a substrate processing system.

FIG. 4 is a flowchart illustrating an example of a substrate processing method according to a first embodiment.

FIG. 5 is a diagram illustrating a structural example of a substrate W in a step ST1.

FIG. 6 is a diagram illustrating a structural example of the substrate W in a step ST2.

FIG. 7 is a diagram illustrating a structural example of a substrate W in a step ST3.

FIG. 8 is a flowchart illustrating an example of a method of forming a mask by plasma etching.

FIG. 9 is a diagram illustrating a structural example of the substrate W in a step ST0-1.

FIG. 10 is a diagram illustrating a structural example of the substrate W in a step ST0-2.

FIG. 11 is a diagram illustrating a structural example of the substrate W in the step ST0-2.

FIG. 12 is a flowchart illustrating an example of a substrate processing method including a step ST4.

FIG. 13 is a flowchart illustrating an example of a substrate processing method when a cycle including the steps ST2 and ST3 is performed a plurality of times.

FIG. 14 is a diagram illustrating a structural example of the substrate W in the step ST3.

FIG. 15 is a diagram illustrating a structural example of the substrate W in the second step ST2.

FIG. 16 is a flowchart illustrating an example of a substrate processing method according to a second embodiment.

FIG. 17 is a diagram illustrating a structural example of the substrate W in the first step ST3.

FIG. 18 is a diagram illustrating a structural example of the substrate W in the step ST2.

FIG. 19 is a diagram illustrating a structural example of the substrate W in the second step ST3.

### DETAILED DESCRIPTION

Hereinafter, each embodiment of the present disclosure will be described.

In one exemplary embodiment, there is provided a substrate processing method including:
(a) providing a substrate including an etching target film and a mask on the etching target film, the mask including sidewalls defining at least one opening,
(b) selectively forming an additional mask containing carbon on the mask by using plasma generated from a processing gas containing carbon and hydrogen, and
(c) etching the etching target film by using plasma generated from an etching gas.

In one exemplary embodiment, (b) is performed after (a).

In one exemplary embodiment, the substrate in (a) includes a first film on the mask, and the substrate processing method further includes (d) removing the first film between (a) and (b).

In one exemplary embodiment, a cycle including (b) and (c) in this order is performed a plurality of times.

In one exemplary embodiment, (c) is performed after (a), and then a cycle including (b) and (c) in this order is performed once or more.

In one exemplary embodiment, the mask has a thickness of 10 μm or less.

In one exemplary embodiment, the mask includes at least one selected from a group consisting of a carbon-containing film, a silicon-containing film, and a metal-containing film.

In one exemplary embodiment, the additional mask has a thickness of 0.2 μm or more.

In one exemplary embodiment, the additional mask has a thickness of 2 μm or less.

In one exemplary embodiment, the additional mask includes an amorphous carbon film.

In one exemplary embodiment, the etching target film includes a film stack including two or more different kinds of silicon-containing films.

In one exemplary embodiment, the etching target film includes a film stack including a silicon oxide film and a silicon nitride film, the silicon oxide film and the silicon nitride film are alternately stacked.

In one exemplary embodiment, an opening of the mask is formed by plasma etching.

In one exemplary embodiment, there is provided a substrate processing system including:
a substrate support that is disposed in a chamber,
a plasma generator, and
a controller, in which
the controller is configured to execute:
   (a) a control of providing a substrate including an etching target film and a mask on the etching target film to a substrate support, the mask including sidewalls defining at least one opening,
   (b) a control of the plasma generator to generate plasma from a processing gas containing carbon and hydrogen to selectively form an additional mask containing carbon on the mask, and
   (c) a control of the plasma generator to generate plasma from an etching gas to etch the etching target film.

In one exemplary embodiment, the substrate processing system further includes:
a plurality of the chambers, and
a transport module configured to transport a substrate to the plurality of chambers in a vacuum atmosphere, in which
the controller is configured to execute the control of (a), (b), and (c) while maintaining the vacuum atmosphere by using any of the plurality of chambers.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on the positional relationship illustrated in the drawings. The dimensional ratio in the drawings does not indicate an actual ratio, and the actual ratio is not limited to the ratio illustrated in the drawings.

### Example of Plasma Processing System

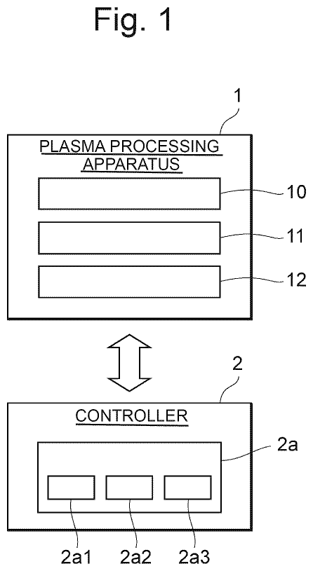

FIG. 1 is a view for explaining an example of a configuration of a capacitively-coupled plasma processing system. In one embodiment, the plasma processing system includes a plasma processing apparatus 1 and a controller 2. The plasma processing system is an example of a substrate processing system and the plasma processing apparatus 1 is an example of a substrate processing apparatus. The plasma processing apparatus 1 includes a plasma processing chamber 10, a substrate support 11 and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected the gas supply 20 to be described below, and the gas exhaust port is connected to the exhaust system 40 to be described below. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be Capacitive Coupled Plasma (CCP), Inductively Coupled Plasma (ICP), Electron-Cyclotron-resonance (ECR) plasma, Helicon Wave Plasma (HWP) or Surface Wave Plasma (SWP). Further, various types of plasma generator including Alternative Current (AC) plasma generator and Direct Current (DC) plasma generator may be used. In one embodiment, an AC signal (AC power) used in the AC plasma generator may have a frequency in the range of 100 kHz to 10 GHz. Accordingly, an AC signal may include Radio Frequency (RF) signal and Microwave signal. In one embodiment, an RF signal may have a frequency in the range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

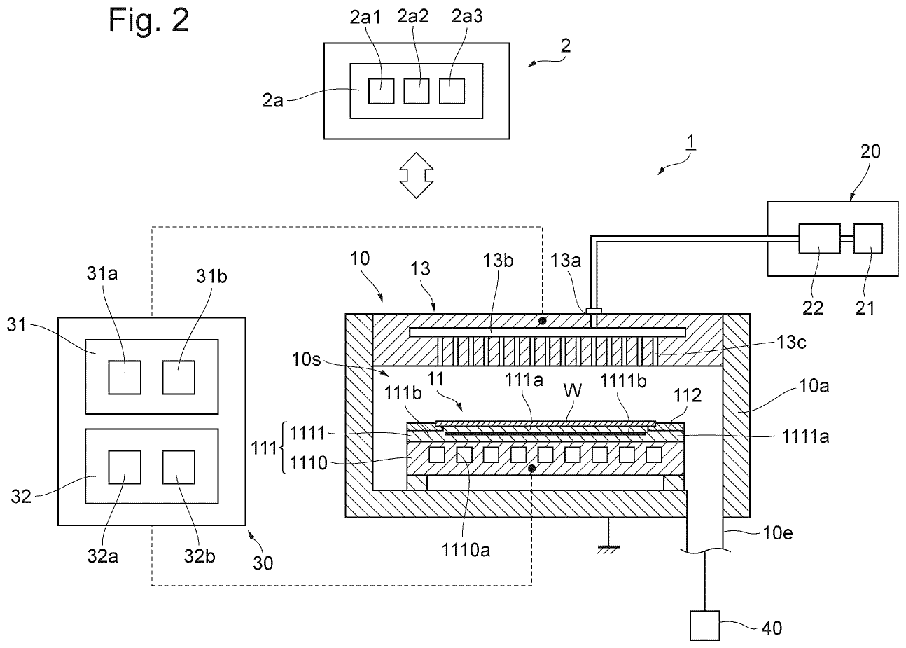

Hereinafter, an example of the configuration example of a plasma processing apparatus will be described. FIG. 2 is a view for explaining an example of a configuration of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting the substrate W and an annular region 111b for supporting the ring assembly 112. The wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 functions as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one embodiment, the ceramic member 1111a also has an annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between the rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a portion of the plasma generator 12. Further, by supplying the bias RF signal (bias signal) to the at least one lower electrode, a bias potential (bias power) is generated in the substrate W, making it possible to draw ion components in the formed plasma into the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

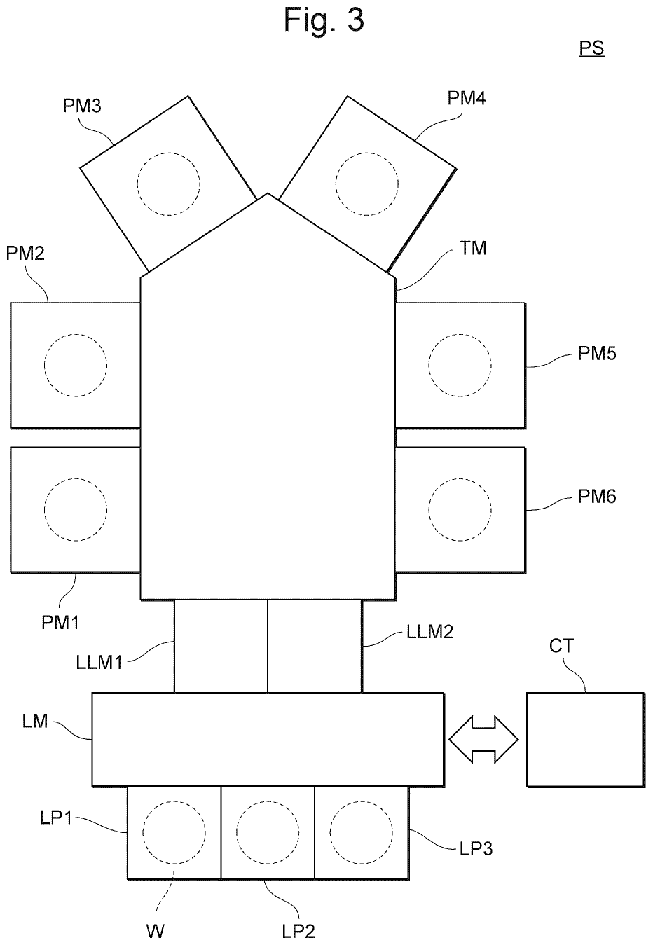

FIG. 3 is a diagram illustrating a configuration example of a substrate processing system. A substrate processing system PS includes substrate processing chambers PM1 to PM6 (hereinafter, also collectively referred to as a “substrate processing module PM”), a transport module TM, load lock modules LLM1 and LLM2 (hereinafter, also collectively referred to as a “load lock module LLM”), a loader module LM, and load ports (LP1 to LP3) (hereinafter, also collectively referred to as a “load port LP”). A controller CT controls each configuration of the substrate processing system PS to execute given processing on the substrate W.

In the substrate processing module PM, etching processing, trimming processing, film formation processing, annealing processing, doping processing, lithography processing, cleaning processing, ashing processing, and the like are executed on the substrate W. A part of the substrate processing module PM may be a capacitively coupled plasma processing apparatus as illustrated in FIG. 2. That is, at least one of the substrate processing chambers PM1 to PM6 may be coupled to a capacitively coupled plasma generator. A part of the substrate processing module PM may be an inductively-coupled plasma processing apparatus. That is, at least one of the substrate processing chambers PM1 to PM6 may be coupled to an inductively-coupled plasma generator. A part of the substrate processing module PM may be a measurement module, and a film thickness of a film formed on the substrate W, dimensions of a pattern formed on the substrate W, and the like may be measured by using, for example, an optical method.

The transport module TM has a transport device that transports the substrate W and transports the substrate W between the substrate processing modules PM or between the substrate processing module PM and the load lock module LLM. The substrate processing module PM and the load lock module LLM are disposed adjacent to the transport module TM. The transport module TM, the substrate processing module PM, and the load lock module LLM are spatially separated or connected by a gate valve that can be opened and closed.

The load lock modules LLM1 and LLM2 are provided between the transport module TM and the loader module LM. The load lock module LLM can switch a pressure therein to an atmospheric pressure or a vacuum. The “atmospheric pressure” may be an external pressure of each module included in the substrate processing system PS. In addition, the “vacuum” is a pressure lower than the atmospheric pressure, and may be, for example, a medium vacuum of 0.1 Pa to 100 Pa. The load lock module LLM transports the substrate W from the loader module LM which has the atmospheric pressure to the transport module TM which has the vacuum, and also transports the substrate W from the transport module TM which has the vacuum to the loader module LM which has the atmospheric pressure.

The loader module LM has a transport device for transporting the substrate W, and transports the substrate W between the load lock module LLM and the load port LP. For example, a front opening unified pod (FOUP) capable of accommodating 25 substrates W or an empty FOUP can be placed in the load port LP. The loader module LM takes out the substrate W from the FOUP in the load port LP and transports the substrate W to the load lock module LLM. Further, the loader module LM takes out the substrate W from the load lock module LLM and transports the substrate W to the FOUP in the load port LP.

The controller CT controls each configuration of the substrate processing system PS to execute given processing on a substrate W. The controller CT stores a recipe in which a process procedure, a process condition, a transport condition, and the like are set, and controls each configuration of the substrate processing system PS to execute given processing on the substrate W according to the recipe. The controller CT may also have some or all of the functions of the controller 2 illustrated in FIG. 1.

### Example of Substrate Processing Method

### First Embodiment

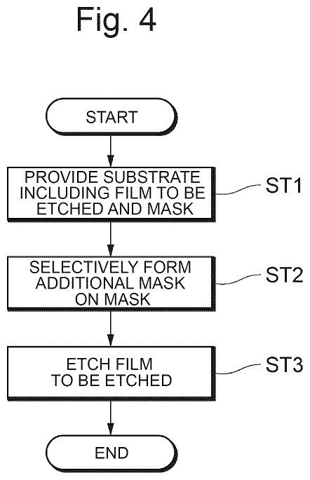

FIG. 4 is a flowchart illustrating an example of a substrate processing method (hereinafter, also referred to as “the present processing method”) according to a first embodiment. As illustrated in FIG. 4, in the embodiment, the present processing method includes a step ST1 of providing a substrate, a step ST2 of selectively forming an additional mask on a mask of the substrate, and a step ST3 of etching an etching target film. In the embodiment, the step ST1, the step ST2, and the step ST3 are performed in this order. In the embodiment, the processing in each step may be executed by a substrate processing system (see FIG. 3). In the following example, the controller CT controls each unit of the substrate processing system, and the present processing method is executed.

### Step ST1: Provision of Substrate

In the embodiment, in Step ST1, as illustrated in FIG. 2, the substrate W is provided in the chamber 10 of the plasma processing apparatus 1. The substrate W is provided in the central region 111a of the substrate support 11 and is held by the substrate support 11 by the electrostatic chuck 1111.

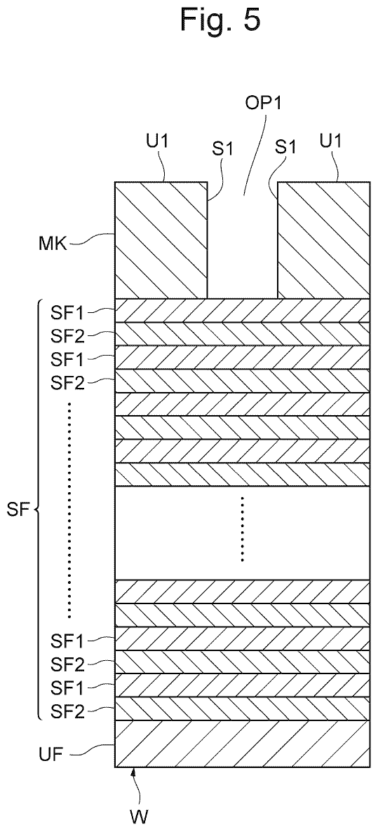

FIG. 5 is a diagram illustrating a configuration example of the substrate W provided in the step ST1. The substrate W includes an underlying film UF, a film stack SF on the underlying film UF, and a mask MK on the film stack SF. The substrate W may be used for manufacturing a semiconductor device. The semiconductor device includes, for example, a memory device such as a DRAM or a 3D-NAND flash memory, and a logic device.

In the embodiment, the underlying film UF is a silicon wafer, an organic film, a dielectric film, a metal film, a semiconductor film, or the like formed on a silicon wafer. The underlying film UF may be configured by stacking a plurality of films.

In the embodiment, the film stack SF is an etching target film in the present processing method. In the embodiment, the film stack SF includes two or more different silicon-containing films. In one embodiment, the film stack SF includes a stacked structure in which a silicon oxide film SF1 and a silicon nitride film SF2 are alternately stacked. The film stack SF may have a thickness of 5 μm or more or 10 μm or more. The film stack SF may have 20 or more layers, 50 or more layers, or 100 or more layers. The film stack SF may include two or more films selected from the group consisting of a single crystal silicon film, a polycrystalline silicon film, a silicon oxide film, and a silicon nitride film.

In the embodiment, the mask MK is a film that functions as a mask in the etching of the film stack SF. The mask MK may be a hard mask. The mask MK includes at least one selected from the group consisting of a carbon-containing film, a silicon-containing film, and a metal-containing film. The mask MK may be an amorphous carbon film. The mask MK may be doped with an element such as phosphorus, boron, or nitrogen. The mask MK may be a film including at least one selected from the group consisting of tungsten carbide (WC), tungsten silicide (WSi), tungsten silicide nitride (WSiN), and tungsten silicide carbide (WSiC). The mask MK may be a single-layer mask including one film, or may be a multi-layer mask including two or more films. The mask MK may have a thickness of 10 μm or less or 5 μm or less.

The mask MK has an upper surface U1 and a sidewall S1 that defines at least one opening OP1 on the film stack SF. The opening OP1 is a space on the film stack SF and is surrounded by the sidewall S1 of the mask MK. That is, the upper surface of the film stack SF has a region covered with the mask MK and a region exposed at the bottom portion of the opening OP1.

The opening OP1 may have any shape in a plan view of the substrate W, that is, when the substrate W is viewed in a direction from the top to the bottom of FIG. 5. The shape may be, for example, a circle, an ellipse, a rectangle, a line, or a shape in which one or more of these are combined. The mask MK may have a plurality of sidewalls S1, and the plurality of sidewalls may define a plurality of openings OP1. The plurality of openings OP1 may each have a linear shape and may be arranged at regular intervals to form a line-and-space pattern. Further, the plurality of openings OP1 may each have a hole shape and may form an array pattern. The width of the opening OP1 may be 120 nm or less, 100 nm or less, 80 nm or less, or 50 nm or less.

Each of the films (the underlying film UF, the film stack SF, and the mask MK) constituting the substrate W may be formed by a chemical vapor deposition (CVD) method, an atomic layer deposition (ALD) method, a molecular layer deposition (MLD) method, a spin coating method, or the like. In the embodiment, at least a part of the step of forming each film on the substrate W may be performed as a part of the step ST1. In the embodiment, all or a part of each film on the substrate W may be performed in the same substrate processing system PS or plasma processing apparatus 1 (chamber 10) as in the step ST1. In addition, after all or a part of each film on the substrate W is formed in an external device or a chamber, the substrate W may be provided in the chamber of the plasma processing apparatus 1 that performs the step ST1.

### Step ST2: Formation of Additional Mask

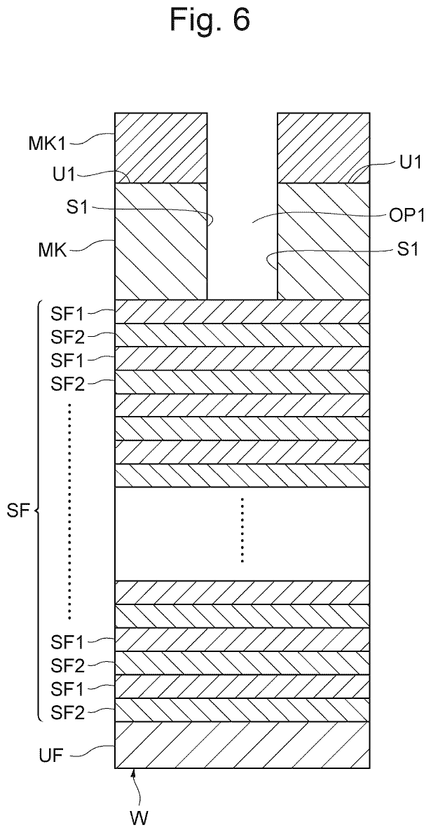

FIG. 6 is a diagram illustrating a configuration example of the substrate W on which an additional mask MK1 is formed in the step ST2. In the embodiment, in the step ST2, the additional mask MK1 is selectively formed on the mask MK of the substrate W. The additional mask MK1 is formed by a plasma CVD method. The term “on the mask MK” includes not only the upper surface of the mask MK but also the upper surface of the film on the upper surface of the mask MK. In addition, the “selectively” includes selecting the exposed portion of the mask MK facing upward from the entire exposed portion of the mask MK.

In the embodiment, in the step ST2, a first processing gas is supplied from the shower head 13 of the plasma processing apparatus 1 illustrated in FIG. 2 into the chamber 10. The temperature of the substrate support 11 or the substrate W may be controlled to a first temperature. The first temperature may be 200° C. or higher.

The first processing gas is a gas containing carbon and hydrogen. The first processing gas may contain a hydrocarbon gas (CxHy) (x and y are an integer of 1 or more). The hydrocarbon gas may be a C₂H₂ gas or a C₃H₆ gas. The first processing gas may further include an inert gas. The inert gas may be a noble gas such as Ar gas, He gas, and Kr gas, or N₂ gas.

In the embodiment, plasma is generated from the first processing gas supplied into the chamber 10. In this case, the source RF signal is supplied from the power source 30 to the upper electrode and/or the lower electrode, and thus, a high-frequency electric field is generated on the substrate support 11, and plasma is generated from the first processing gas in the plasma processing space 10s. The source RF signal has a frequency of 40 MHz or more. The source RF signal has a first power. The first power may be in a range of 100 W to 500 W.

During plasma generation, a bias signal is supplied to the substrate support 11. The bias signal may be a bias RF signal supplied from the RF power source 31 or a bias DC signal supplied from the DC power source 32. The bias DC signal may be a direct current pulse voltage. The absolute value of the direct current pulse voltage may be 200 V or less. The duty ratio of the direct current pulse voltage may be 20% or less, and may be in a range of 5% to 20%, for example, about 10%. In addition, the frequency of the direct current pulse voltage may be in a range of 100 KHz to 1000 KHz. A bias potential is generated between the plasma and the substrate W, and ions and radicals in the plasma are attracted to the substrate W.

As illustrated in FIG. 6, in the embodiment, carbon ions in the plasma are selectively deposited on the upper surface U1 of the mask MK, and the additional mask MK1 is formed. The deposition of the mask MK on the sidewall S1 is blocked by hydrogen radicals in the plasma. The additional mask MK1 is formed substantially only on the upper surface U1 of the mask MK. The additional mask MK1 has a thickness of 0.2 μm or more. The additional mask MK1 has a thickness of 2 μm or less. The thickness of the mask MK and the additional mask MK1 may be 6 μm or more or 10 μm or more.

### Step ST3: Etching of Film Stack SF

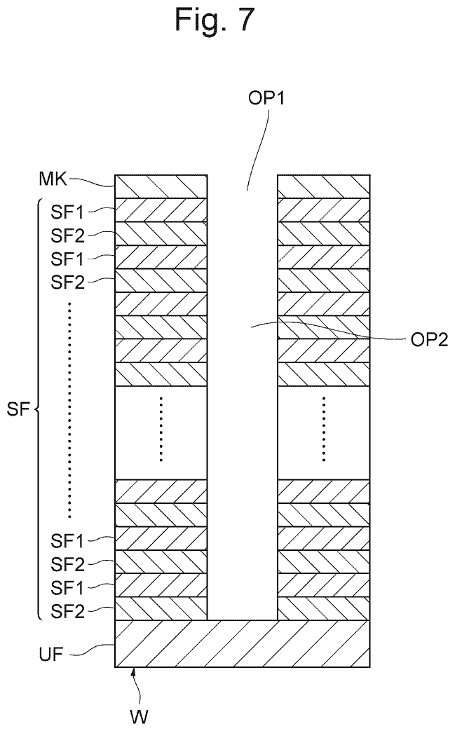

FIG. 7 is a diagram illustrating a configuration example of the substrate W in which the film stack SF is etched in the step ST3. In the step ST3, the film stack SF is etched by using the plasma generated from an etching gas. The step ST3 may be performed in the same chamber of the plasma processing apparatus 1 as in the step ST2, or may be performed in a chamber of another plasma processing apparatus 1. When performed in another plasma processing apparatus 1, the substrate W may be transported from the plasma processing apparatus 1 in which the step ST2 is performed to another plasma processing apparatus 1 in the substrate processing system PS.

In the embodiment, in the step ST3, the etching gas is supplied from the shower head 13 illustrated in FIG. 2 into the plasma processing space 10s. The etching gas may include a hydrogen fluoride gas and at least one carbon-containing gas selected from the group consisting of a CF gas (fluorocarbon gas) and a CHF gas (hydrofluorocarbon gas). In the embodiment, the etching gas may include a hydrogen fluoride gas, a CF gas, a CHF gas, an oxygen-containing gas, and a fluorine-containing gas that does not contain carbon.

In the embodiment, plasma is generated from the etching gas supplied into the chamber 10. In this case, the source RF signal is supplied from the power source 30 to the upper electrode and/or the lower electrode, and thus, a high-frequency electric field is generated on the substrate support 11, and plasma is generated from the etching gas in the plasma processing space 10s. The source RF signal may have a frequency of 13 MHz or more. The source RF signal may have the first power. The first power may be 1 kW or more.

During plasma generation, a bias signal is supplied to the substrate support 11. The bias signal may be a bias RF signal supplied from the RF power source 31 or a bias DC signal supplied from the DC power source 32. A bias potential is generated between the plasma and the substrate W. Active species such as ions and radicals in the plasma are attracted to the substrate W, and the film stack SF is etched by the active species. The etching may be an anisotropic etching using fluorocarbon gas plasma or hydrofluorocarbon gas plasma.

As illustrated in FIG. 7, in the embodiment, in the film stack SF, a portion (a portion exposed in the opening OP1) that is not covered by the mask MK and the additional mask MK1 is etched, and an opening OP2 is formed in the film stack SF. In the film stack SF, the opening OP2 having an aspect ratio (A/R) of 100 or more may be formed. The opening OP2 may have, for example, a critical dimension (CD) of 80 nm or less and a depth of 10 μm or more.

Thereafter, the mask MK of the substrate W is removed by ashing. The ashing of the mask MK may be performed by using, for example, oxygen-based gas plasma.

According to the present exemplary embodiment, the substrate processing method includes the step ST1 of providing a substrate, the step ST2 of selectively forming the additional mask MK1 containing carbon on the mask MK by using plasma generated from a processing gas containing carbon and hydrogen, and a step ST3 of etching an etching target film by using plasma generated from an etching gas. In general, as the mask becomes thicker (the opening becomes deeper), the dimensional accuracy of the opening formed in the mask decreases. According to the present exemplary embodiment, since the additional mask MK1 is added to the mask MK later, the thickness of the mask MK at the time of initial formation can be suppressed, and thus, the dimensional accuracy of the opening of the mask MK can be improved. As a result, the etching shape when the etching target film is etched by using the mask can be improved.

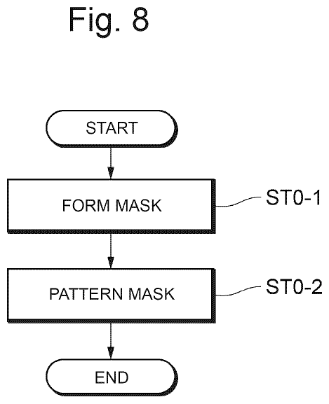

In the present exemplary embodiment, the opening OP1 of the mask MK is formed by plasma etching. In this case, as illustrated in FIG. 8, the present processing method may include a step ST0-1 of forming the mask MK on the film stack SF and a step ST0-2 of patterning the mask MK to form the opening OP1.

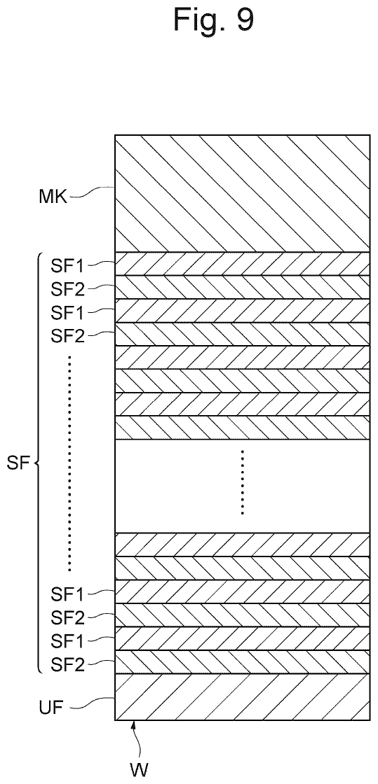

In the embodiment, in the step ST0-1, as illustrated in FIG. 9, the mask MK is formed on the film stack SF. The mask MK may be formed by various methods such as a CVD method, an ALD method, an MLD method, and a spin coating method.

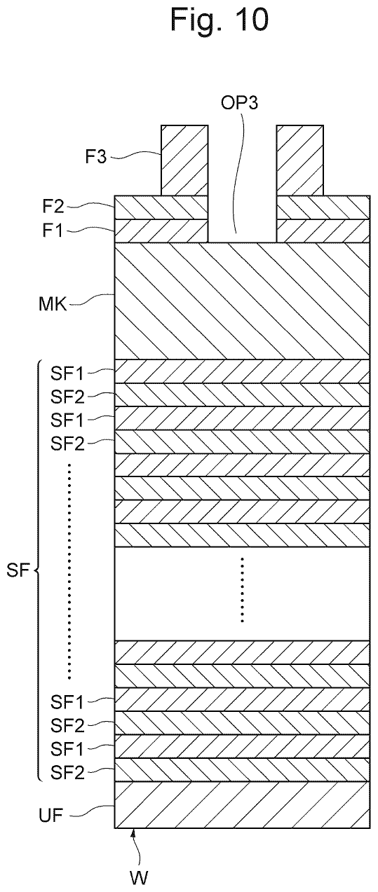

In the step ST0-2, as illustrated in FIG. 10, the first film F1 having an opening OP3 is formed on the mask MK. The first film F1 may be a silicon-containing film. The opening OP3 of the first film F1 is formed by a lithography processing. In this case, first, a flat first film F1 is formed on the mask MK, and an antireflection film F2 and a resist film F3 are formed on the first film F1. Next, a resist pattern having an opening pattern is formed by the exposure processing and the development processing, and then the first film F1 is etched by using the resist pattern. As a result, the opening OP3 is formed in the first film F1.

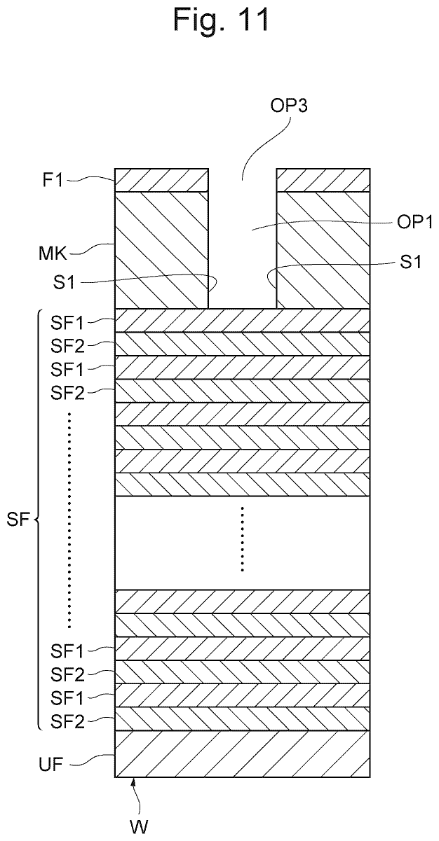

Thereafter, as illustrated in FIG. 11, the mask MK is etched by using the first film F1 including the opening OP3 as a mask, and the opening OP1 is formed. The step ST0-1 and/or the step ST0-2 may be performed in the same substrate processing system PS as in the step ST2 or the step ST3.

When the opening OP1 of the mask MK is formed by plasma etching, if the mask MK is thick, the vertical component of ions in the plasma may be lost during the plasma etching. In this case, the lower part of the opening of the mask MK may be narrowed, the sidewall of the opening of the mask MK may be etched in the lateral direction, and a shape defect may occur in the opening of the mask MK. According to the present exemplary embodiment, since the additional mask MK1 is formed in the step ST2, the thickness of the mask MK can be suppressed when the opening OP1 of the mask MK is formed. As a result, the shape defect of the opening of the mask MK can be avoided, and as a result, the etching shape of the etching target film can be improved.

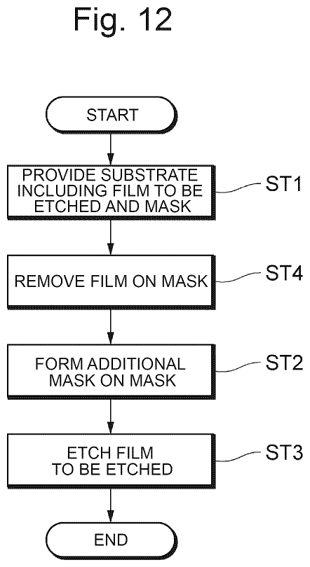

In the present exemplary embodiment, the substrate W provided in the step ST1 may have the first film F1 on the mask MK. The first film F1 may be a film remaining after etching for forming the opening OP1 of the mask MK. In this case, as illustrated in FIG. 12, the present processing method may include a step ST4 of removing the first film F1 between the step ST1 and the step ST2.

In the step ST4, the first film F1 is removed by a processing gas or a processing liquid. The first film F1 may be removed by using, for example, a chemical liquid obtained by mixing HF and water. As a result, the upper surface U1 of the mask MK is flattened. In the next step ST2, the additional mask MK1 is formed on the flattened mask MK.

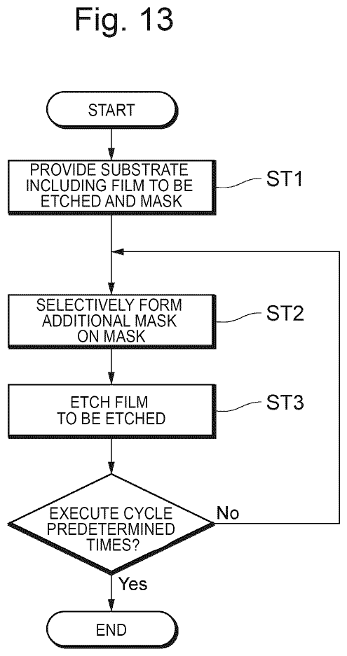

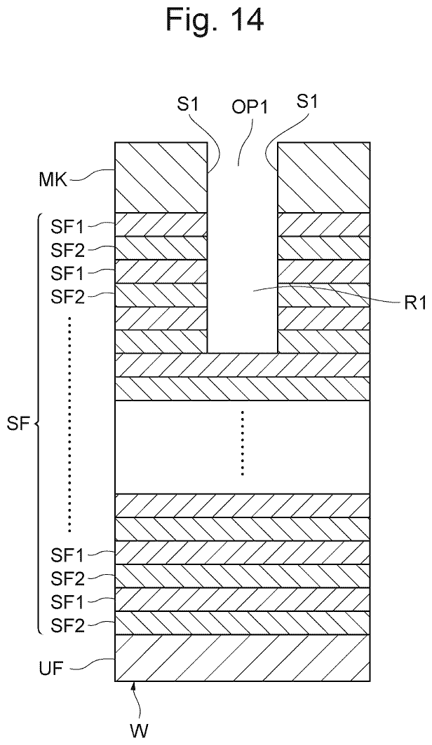

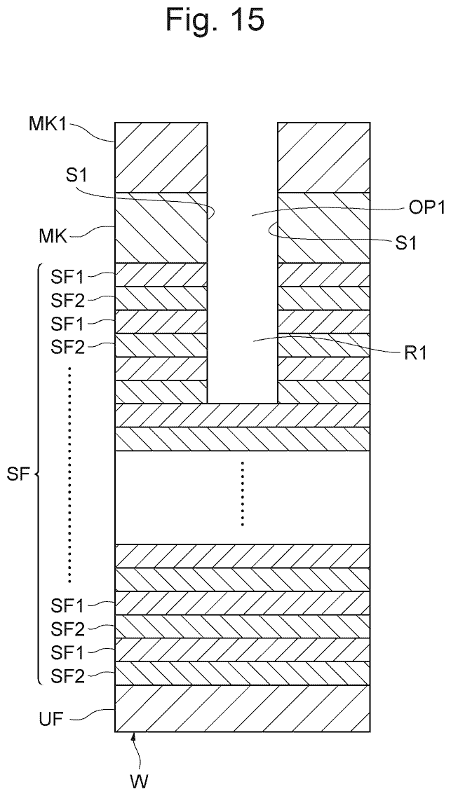

In the present exemplary embodiment, a cycle including the step ST2 and the step ST3 in this order may be performed a plurality of times. FIG. 13 is a flowchart illustrating an example of the present processing method. As illustrated in FIG. 14, in the step ST3, in the film stack SF, a portion (a portion exposed in the opening OP1) that is not covered with the mask MK and the additional mask MK1 is etched, and a recess portion R1 is formed in a part of the film of the film stack SF. When the cycle including the step ST2 and the step ST3 is not performed a predetermined number of times set in advance, the step ST2 and the step ST3 are performed again. As illustrated in FIG. 15, the additional mask MK1 is formed on the mask MK, and then the film stack SF is further deeply etched at the bottom of the recess portion R1. Then, when the cycle including the step ST2 and the step ST3 is performed a predetermined number of times, the present processing method is ended. In this case, the opening OP2 as illustrated in FIG. 7 may be formed in the film stack SF. A predetermined number of times of the cycles may be 2 times or more, 5 times or more, or 10 times or more. When the mask MK has a thickness smaller than a predetermined thickness in the step ST3, the cycles of the step ST2 and the step ST3 may be performed again.

When the etching target film is plasma-etched by using a mask, as the mask is gradually scraped and the film thickness of the remaining mask is reduced, the sidewall is etched in the lateral direction at the opening of the etching target film, and so-called bowing may occur. According to the present exemplary embodiment, since the cycle including the step ST2 and the step ST3 in this order is performed a plurality of times, the additional mask MK1 can be added during the etching, and the film thickness of the entire mask can be maintained. As a result, the bowing is suppressed, and the etching shape of the etching target film can be improved.

### Second Embodiment

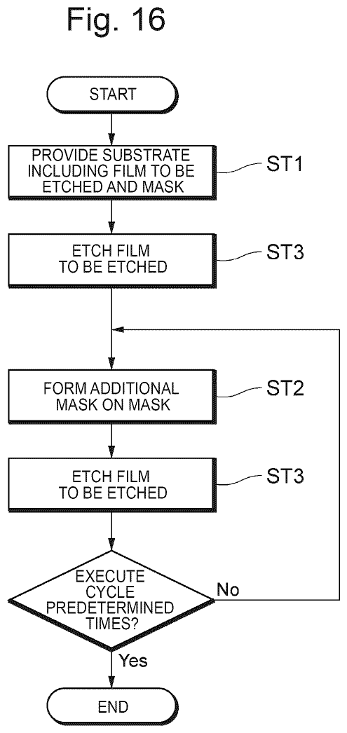

In the present exemplary embodiment, in the present processing method, after the step ST1, the step ST3 is performed, and then the cycle including the step S2 and the step ST3 is performed once or more in the order. FIG. 16 is a flowchart illustrating an example of the present processing method.

In the embodiment, in step ST1, as illustrated in FIG. 5, a substrate W including the underlying film UF, a film stack SF on the underlying film UF, and a mask MK on the film stack SF is provided. The substrate W is provided in a chamber 10 of a plasma processing apparatus 1 in which the step ST3 is performed.

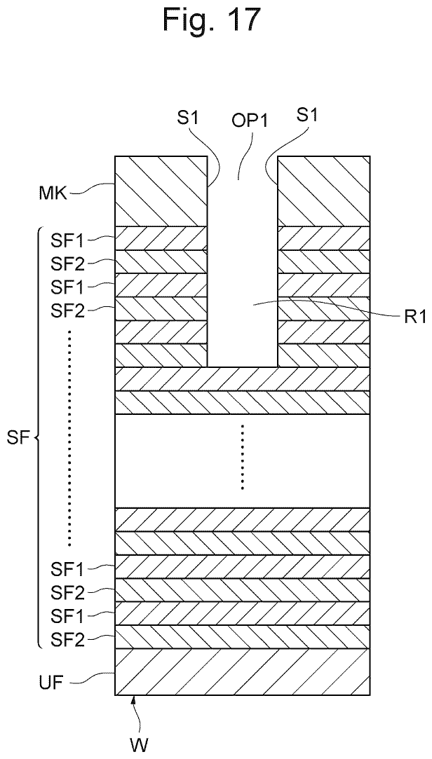

Next, the step ST3 is performed, and the film stack SF is etched by using the plasma generated from the etching gas. As illustrated in FIG. 17, in the embodiment, a portion of the film stack SF that is not covered by the mask MK (a portion exposed in the opening OP1) is etched, and the recess portion R1 is formed in the film stack SF.

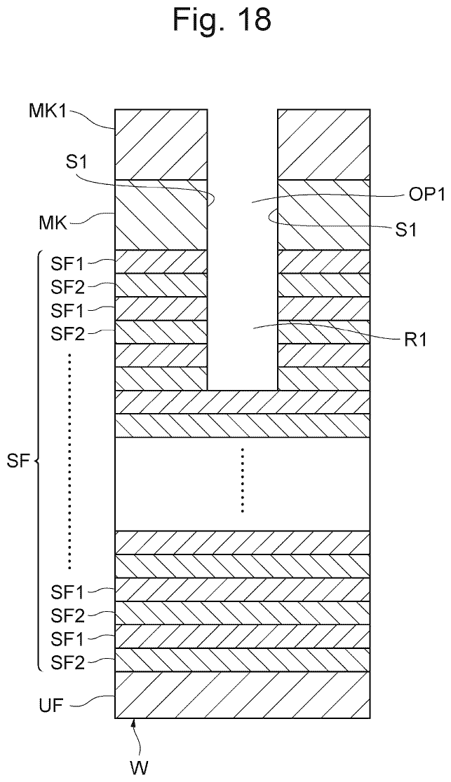

Next, the step ST2 is performed, and as illustrated in FIG. 18, an additional mask MK1 is selectively formed on the mask MK of the substrate W.

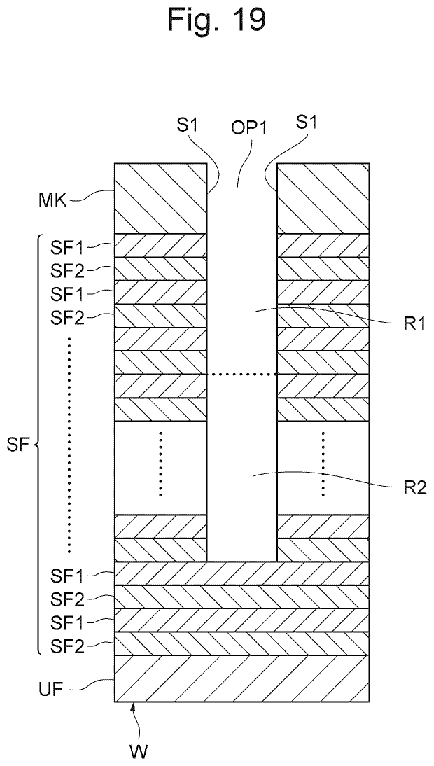

Next, the step ST3 is performed, and as illustrated in FIG. 19, the film stack SF is etched by using the plasma generated from an etching gas. In the film stack SF, a portion (a portion exposed in the opening OP1) that is not covered by the mask MK and the additional mask MK1 is etched, and a deeper recess portion R2 is further formed in the film stack SF.

When the cycle including the step ST2 and the step ST3 is not performed a predetermined number of times set in advance, the step ST2 and the step ST3 are performed again. When the cycle including the step ST2 and the step ST3 is performed a predetermined number of times, the present processing method is ended. In this case, an opening OP2 as illustrated in FIG. 7 may be formed in the film stack SF. The cycle including the step ST2 and the step ST3 may be performed two or more times. Various conditions of each step in the present embodiment may be the same as those in the first embodiment.

According to the present exemplary embodiment, since the cycle including the step ST2 and the step ST3 in this order is performed once or more after the step ST1 and the step ST3, the additional mask MK1 can be added during the etching, and the film thickness of the entire mask can be maintained. As a result, the etching shape of the etching target film can be improved.

In the above first and second embodiments, when the step ST2 and the step ST3 are repeated, in the substrate processing system PS, the substrate may be continuously processed while maintaining a vacuum atmosphere by using the transport module TM and any of the substrate processing chambers PM1 to PM6.

The etching target film in the first and second embodiments described above is not limited to the film stack SF. The etching target film may be at least one single-layer film or a multi-layer films selected from the group consisting of a single crystal silicon film, a polycrystalline silicon film, a silicon oxide film, and a silicon nitride film.

In the first and second embodiments described above, the present processing method is not limited to the inductively-coupled plasma processing apparatus, and may be performed by other types of plasma processing apparatuses, for example, a plasma processing apparatus that generates capacitive coupled plasma, a plasma processing apparatus that generates ECR plasma, a plasma processing apparatus that generates helical wave excited plasma, or a plasma processing apparatus that generates surface wave plasma.

The embodiments of the present disclosure further include the following aspects.

### Addendum 1

A substrate processing method including:
(a) providing a substrate including a etching target film and a mask on the etching target film, the mask including sidewalls defining at least one opening,
(b) selectively forming an additional mask containing carbon on the mask by using plasma generated from a processing gas containing carbon and hydrogen, and
(c) etching the etching target film by using plasma generated from an etching gas.

### Addendum 2

The substrate processing method according to Addendum 1, in which
the (b) is performed after the (a).

### Addendum 3

The substrate processing method according to Addendum 2, in which
the substrate in the (a) includes a first film on the mask, and
the substrate processing method further includes (d) removing the first film between the (a) and the (b).

### Addendum 4

The substrate processing method according to Addendum 2 or 3, in which
a cycle including the (b) and the (c) in this order is performed a plurality of times.

### Addendum 5

The substrate processing method according to Addendum 1, in which
the (c) is performed after the (a), and then a cycle including the (b) and the (c) in this order is performed once or more.

### Addendum 6

The substrate processing method according to any one of Addenda 1 to 5, in which
the mask has a thickness of 10 μm or less.

### Addendum 7

The substrate processing method according to any one of Addenda 1 to 6, in which
the mask includes at least one selected from a group consisting of a carbon-containing film, a silicon-containing film, and a metal-containing film.

### Addendum 8

The substrate processing method according to any one of Addenda 1 to 7, in which
the additional mask has a thickness of 0.2 μm or more.

### Addendum 9

The substrate processing method according to any one of Addenda 1 to 8, in which
the additional mask has a thickness of 2 μm or less.

### Addendum 10

The substrate processing method according to any one of Addenda 1 to 9, in which
the additional mask includes an amorphous carbon film.

### Addendum 11

The substrate processing method according to any one of Addenda 1 to 10, in which
the etching target film includes a film stack including two or more different kinds of silicon-containing films.

### Addendum 12

The substrate processing method according to any one of Addenda 1 to 11, in which
the etching target film includes a film stack including a silicon oxide film and a silicon nitride film, the silicon oxide film and the silicon nitride film are alternately stacked.

### Addendum 13

The substrate processing method according to any one of Addenda 1 to 12, in which
the opening of the mask is formed by plasma etching.

### Addendum 14

A substrate processing system including:
a substrate support that is disposed in a chamber,
a plasma generator, and
a controller, in which
   the controller is configured to execute:
      (a) a control of providing a substrate including a etching target film and a mask on the etching target film to the substrate support, the mask including sidewalls defining at least one opening,
   (b) a control of the plasma generator to generate plasma from a processing gas containing carbon and hydrogen to selectively form an additional mask containing carbon on the mask, and
   (c) a control of the plasma generator to generate plasma from an etching gas to etch the etching target film.

### Addendum 15

The substrate processing system according to Addendum 14, further including:
a plurality of the chambers, and
a transport module configured to transport a substrate to the plurality of chambers in a vacuum atmosphere, in which
the controller is configured to execute the control of the (a), the (b), and the (c) while maintaining the vacuum atmosphere by using any of the plurality of chambers.

Each of the above embodiments is described for the purpose of description, and is not intended to limit the scope of the present disclosure. Each of the above embodiments may be modified in various ways without departing from the scope and purpose of the present disclosure. For example, some elements in one embodiment can be added to other embodiments. In addition, some elements in one embodiment can be replaced with corresponding elements in other embodiments.

According to one exemplary embodiment of the present disclosure, it is possible to provide a technology for improving an etching shape of a etching target film.

What is claimed is:

1. A substrate processing method comprising:
(a) providing a substrate including an etching target film and a mask on the etching target film, the mask including sidewalls defining at least one opening;
(b) selectively forming an additional mask containing carbon on the mask by using plasma generated from a processing gas containing carbon and hydrogen; and
(c) etching the etching target film by using plasma generated from an etching gas.

2. The substrate processing method according to claim 1, wherein
the (b) is performed after the (a).

3. The substrate processing method according to claim 2, wherein
the substrate in the (a) includes a first film on the mask, and
the substrate processing method further comprises (d) removing the first film between the (a) and the (b).

4. The substrate processing method according to claim 2, wherein
a cycle including the (b) and the (c) in this order is performed a plurality of times.

5. The substrate processing method according to claim 1, wherein
the (c) is performed after the (a), and then a cycle including the (b) and the (c) in this order is performed once or more.

6. The substrate processing method according to claim 1, wherein
the mask has a thickness of 10 μm or less.

7. The substrate processing method according to claim 1, wherein
the mask includes at least one selected from a group consisting of a carbon-containing film, a silicon-containing film, and a metal-containing film.

8. The substrate processing method according to claim 1, wherein
the additional mask has a thickness of 0.2 μm or more.

9. The substrate processing method according to claim 1, wherein
the additional mask has a thickness of 2 μm or less.

10. The substrate processing method according to claim 1, wherein
the additional mask includes an amorphous carbon film.

11. The substrate processing method according to claim 1, wherein
the etching target film includes a film stack including two or more different kinds of silicon-containing films.

12. The substrate processing method according to claim 1, wherein
the etching target film includes a film stack including a silicon oxide film and a silicon nitride film, the silicon oxide film and the silicon nitride film are alternately stacked.

13. The substrate processing method according to claim 1, wherein
the opening of the mask is formed by plasma etching.

14. A substrate processing system comprising:
a substrate support that is disposed in a chamber;
a plasma generator; and
a controller, wherein
the controller is configured to execute:
(a) a control of providing a substrate including an etching target film and a mask on the etching target film to the substrate support, the mask including sidewalls defining at least one opening,
(b) a control of the plasma generator to generate plasma from a processing gas containing carbon and hydrogen to selectively form an additional mask containing carbon on the mask, and
(c) a control of the plasma generator to generate plasma from an etching gas to etch the etching target film.

15. The substrate processing system according to claim 14, further comprising:
a plurality of the chambers; and
a transport module configured to transport a substrate to the plurality of chambers in a vacuum atmosphere, wherein
the controller is configured to execute the control of the (a), the (b), and the (c) while maintaining the vacuum atmosphere by using any of the plurality of chambers.
